(19) United States
(12) Patent Application Publication
(10) Pub. No.: US 2025/0261313 A1
(43) Pub. Date: Aug. 14, 2025

(54) SEMICONDUCTOR DEVICE AND MANUFACTURING METHOD OF SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yuzeng LIU, Toyonaka Osaka (JP); Shuzo ARATANI, Ibo Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/190,947

(22) Filed: Apr. 28, 2025

Related U.S. Application Data
(63) Continuation of application No. PCT/JP2024/005466, filed on Feb. 16, 2024.

(30) Foreign Application Priority Data
Jul. 31, 2023 (JP) 2023-124895

(51) Int. Cl. H05K 1/18; H01L 23/00; H05K 3/32

(52) U.S. Cl. CPC H05K 1/181; H05K 3/32; H01L 24/29; H01L 24/32; H01L 24/45; H01L 24/48; H01L 24/73; H01L 24/83; H01L 24/85; H01L 2224/29139; H01L 2224/29147; H01L 2224/32225; H01L 2224/45124; H01L 2224/48225; H01L 2224/73265; H01L 2224/8384; H01L 2224/85205; H01L 2924/10272; H05K 2201/10757; H05K 2201/10909; H05K 2201/10916; H05K 2203/1131

(57) ABSTRACT

A semiconductor device according to an embodiment includes an insulating board having a circuit pattern, a semiconductor chip fixed on the insulating board and electrically-connected with the circuit pattern, and a power terminal that includes metal of a same type as the circuit pattern, and is electrically-connected with the circuit pattern, in which the power terminal includes a bond portion to be bonded with the circuit pattern, the bond portion having a plate shape, a penetrating portion penetrating through the bond portion in a thickness direction of the bond portion, and an extending portion that extends upward by bending from one end portion of the bond portion, and is configured to be able to connect the circuit pattern and an external device, and the bond portion and the circuit pattern are bonded by a bonding material containing particles of metal of a same type as the power terminal and the circuit pattern.

### CROSS-REFERENCE TO RELATED APPLICATIONS

This application is a continuation application of International Application No. PCT/JP2024/005466, filed Feb. 16, 2024, incorporated herein by reference, and which claims the benefit of priority from Japanese Patent Application No. 2023-124895, filed Jul. 31, 2023, the entire contents of which are incorporated herein by reference.

### FIELD

Embodiments described herein relate generally to a semiconductor device and a manufacturing method of a semiconductor device.

### BACKGROUND

When a semiconductor device is manufactured, processing of bonding an external terminal such as a power terminal and a signal terminal, and a circuit pattern of an insulating board on which a semiconductor chip is mounted is performed in some cases. The external terminal and the circuit pattern are ultrasonic-bonded while load being applied, for example. The circuit pattern and the external terminal can be thereby electrically-bonded by breaking coats formed on the surface of these by natural oxidation.

### BRIEF DESCRIPTION OF THE DRAWINGS

FIG. 1 is a schematic diagram illustrating an example of a configuration of a semiconductor device according to an embodiment;

FIGS. 2A to 2C are enlarged views of a bond portion included in a power terminal according to an embodiment;

FIG. 3 is an enlarged perspective view of a bond portion included in a signal terminal according to an embodiment;

FIGS. 4A to 4C are longitudinal sectional views illustrating an example of a procedure of a manufacturing method of a semiconductor device according to an embodiment;

FIGS. 5A and 5B are longitudinal sectional views illustrating an example of a procedure of a manufacturing method of a semiconductor device according to an embodiment;

FIGS. 6A and 6B are longitudinal sectional views illustrating an example of a procedure of a manufacturing method of a semiconductor device according to an embodiment;

FIGS. 7A and 7B are longitudinal sectional views illustrating an example of a procedure of a manufacturing method of a semiconductor device according to an embodiment;

FIGS. 8A and 8B are longitudinal sectional views illustrating states of connection of power terminals according to an embodiment and a comparative example to a circuit pattern;

FIGS. 9A and 9B are enlarged views of a bond portion included in a power terminal according to Modified Example 1 of an embodiment; and

FIGS. 10A to 10D are bottom-side plan views of a bond portion included in a power terminal according to Modified Example 2 of an embodiment.

### DETAILED DESCRIPTION

A semiconductor device according to an embodiment includes an insulating board having a circuit pattern, a semiconductor chip fixed on the insulating board and electrically-connected with the circuit pattern, and a power terminal that includes metal of a same type as the circuit pattern, and is electrically-connected with the circuit pattern, in which the power terminal includes a bond portion to be bonded with the circuit pattern, the bond portion having a plate shape, a penetrating portion penetrating through the bond portion in a thickness direction of the bond portion, and an extending portion that extends upward by bending from one end portion of the bond portion, and is configured to be able to connect the circuit pattern and an external device, and the bond portion and the circuit pattern are bonded by a bonding material containing particles of metal of a same type as the power terminal and the circuit pattern.

Exemplary embodiments of the present invention will be explained below in detail with reference to the accompanying drawings. In addition, the present invention is not limited to the following embodiments. Further, components in the following embodiments include components that can be easily conceived by the one skilled in the art, or substantially the same components.

### (Configuration Example of Semiconductor Device)

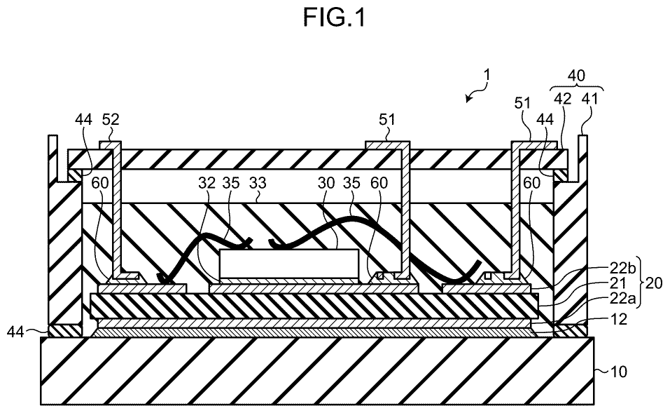

FIG. 1 is a longitudinal sectional view illustrating an example of a configuration of a semiconductor device 1 according to an embodiment; As illustrated in FIG. 1, the semiconductor device 1 of the embodiment includes a base plate 10, a circuit board 20, a semiconductor chip 30, a package 40, a power terminal 51, and a signal terminal 52.

The base plate 10 is a plate-like member formed by AlSiC, for example. The base plate 10 functions as a support member that supports the entire semiconductor device 1, and also functions as a heatsink that radiates heat generated at the time of the operation of the semiconductor chip 30.

The circuit board 20 is provided on the base plate 10. The circuit board 20 includes an insulating board 21, and circuit patterns 22a and 22b provided on both sides of the insulating board 21.

The insulating board 21 is a flat plate made of ceramic such as SiN and AlN, for example. The circuit patterns 22a and 22b are made of Cu, for example. The circuit pattern 22a is provided on the bottom surface side of the insulating board 21 in such a manner as to face the base plate 10, and connected to the base plate 10 by solder 12. The circuit pattern 22b is provided on the top surface side of the insulating board 21.

The semiconductor chip 30 is fixed to the circuit pattern 22b of the circuit board 20 on the bottom surface. The semiconductor chip 30 and the circuit pattern 22b are fixed by a sintered material 32 such as Cu or Ag, for example. The sintered material 32 of Cu, Ag, or the like is obtained by sintering Cu paste, Ag paste, or the like.

The semiconductor chip 30 is, for example, a Metal-Oxide-Semiconductor Field-Effect Transistor (MOSFET), or the like, and its material is SiC. In a case where the semiconductor chip 30 is a MOSFET, the semiconductor chip 30 includes a gate pad serving as a gate electrode, a P-electrode serving as a drain electrode, and an N-electrode serving as a source electrode. That is, the gate electrode and the N-electrode serving as a source electrode are provided on the top surface of the semiconductor chip 30, and the P-electrode serving as a drain electrode is provided on the bottom surface of the semiconductor chip 30 bonded with the circuit pattern 22b.

A semiconductor chip made of SiC is high-temperature-tolerant, and can operate highly reliably at high temperature. The above-described sintered material 32 obtained by sintering Cu paste, Ag paste, or the like is a material with less degradation even under a high-temperature operating environment of the semiconductor chip 30 made of SiC.

Further, the semiconductor chip 30 on the top surface of the semiconductor chip 30 is electrically-connected to the circuit pattern 22b near the semiconductor chip 30 by a wire 35 such as an Al material. The wire 35 that connects the semiconductor chip 30 and the circuit pattern 22b includes a gate wire that connects the gate electrode of the semiconductor chip 30 and the circuit pattern 22b, a wire that connects the N-electrode serving as a source electrode of the semiconductor chip 30, and the circuit pattern 22b, and the like.

The package 40 includes a rectangular case 41 that surrounds the circuit board 20 on the base plate 10, the semiconductor chip 30, and the like, and a lid 42 that blocks the rectangular case 41, for example. The case 41 and the lid 42 may be made of, for example, thermoplastic Poly Phenylene Sulfide (PPS) resin, or the like. The case 41 is fixed to the base plate 10 by a joining material 44 such as silicone resin. The lid 42 is similarly fixed to an upper end portion of the case 41 by the joining material 44 such as silicone resin.

The power terminal 51 and the signal terminal 52 are elongated members made of Cu, one end portion is connected to the circuit pattern 22b of the circuit board 20 by a Cu sintered material 60, and a different end portion is folded in such a manner as to follow the top surface of the lid 42 of the package 40. The power terminal 51 and the signal terminal 52 preferably include oxygen-free copper (C1020) or the like.

The power terminal 51 and the signal terminal 52 function as an external terminal that connects the semiconductor chip 30 to an external device of the semiconductor device 1 or the like via the circuit board 20. In addition, the power terminal 51 includes, for example, a P-terminal electrically-connected to the P-electrode of the semiconductor chip 30, an N-terminal electrically-connected to the N-electrode of the semiconductor chip 30, and an AC terminal (not illustrated) being an output terminal, and the like.

The Cu sintered material 60 serving as a bonding material can be obtained by sintering pressureless Cu paste, for example. In other words, as described later, by interposing the pressureless Cu paste between an external terminal such as the power terminal 51 and the circuit pattern 22b, and heating and sintering the pressureless Cu paste, it is possible to bond the external terminal and the circuit pattern 22b.

Here, the power terminal 51 and the signal terminal 52, and the circuit pattern 22b mainly include Cu, for example. By using pressureless Cu paste containing metal of the same type that is highly compatible with metal included in the power terminal 51 and the signal terminal 52, and the circuit pattern 22b, it is possible to firmly bond the power terminal 51 and the signal terminal 52, and the circuit pattern 22b. Further, for example, by using pressureless Cu paste instead of Ag paste containing expensive Ag, or the like, it is possible to save the manufacturing cost of the semiconductor device 1.

The pressureless Cu paste is a material processed into a paste by dispersing nanosized Cu particles in an organic solvent, for example. The organic solvent includes, for example, an organic protective agent, a sintering accelerator, and the like. The organic solvent is a carboxylic compound, for example. The organic protective agent protects Cu particles in the pressureless Cu paste, achieves homogenization by dispersing nanosized-Cu particles, and suppresses bonding by the pressureless Cu paste at normal temperature. The sintering accelerator accelerates the sintering of the pressureless Cu paste when the pressureless Cu paste is heated.

Further, the pressureless Cu paste can be used for bonding with another member by being sintered by being heated at a predetermined temperature, without applying load. In the pressureless Cu paste, by using an organic protective agent different from pressed Cu paste to be sintered with load being applied, such as an organic protective agent dissolving at relatively-low temperature, for example, pressureless bonding is made executable.

By being formed from such pressureless Cu paste, in the Cu sintered material 60, Cu particles contained in the pressureless Cu paste or their traces can be observed. Further, the Cu sintered material 60 may contain a void generated by an organic solvent vaporized in sintering.

In addition, the circuit board 20, the semiconductor chip 30, and the like in the package 40, including connection portions with the power terminal 51 and the signal terminal 52, and the circuit board 20, are sealed by a potting material 33 such as silicone gel, for example.

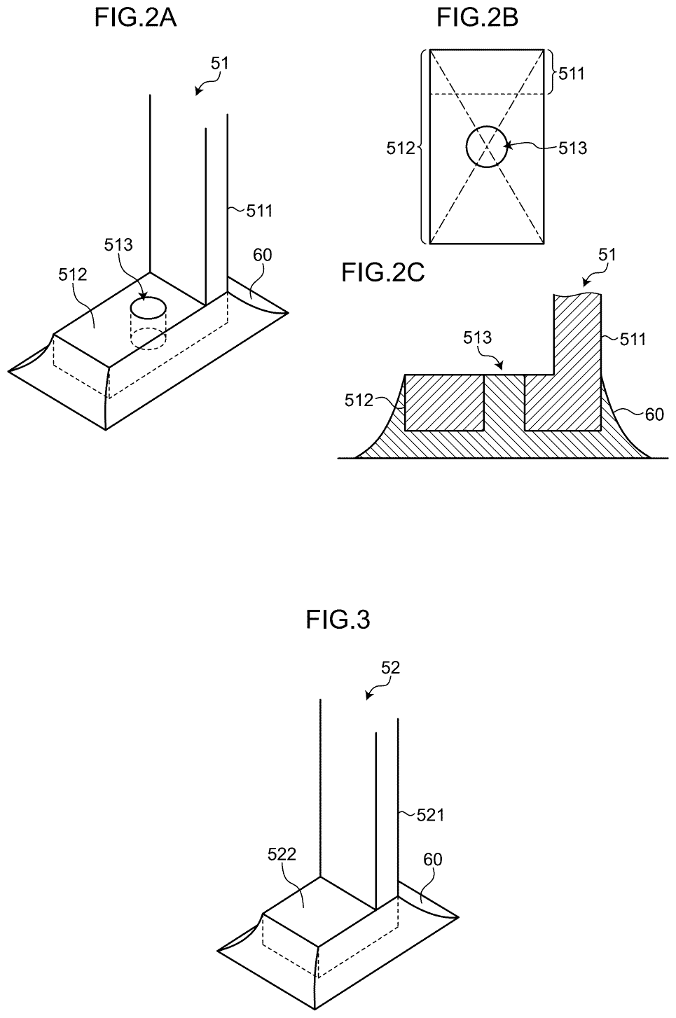

Next, a more detailed configuration example of connection portions with the power terminal 51 and the signal terminal 52, and the circuit board 20 will be described using FIGS. 2A to 3.

FIGS. 2A to 2C are enlarged views of a bond portion 512 included in the power terminal 51 according to an embodiment. More specifically, FIG. 2A is a perspective view of the bond portion 512, FIG. 2B is a bottom-side plan view of the bond portion 512, and FIG. 2C is a longitudinal sectional view of the bond portion 512 viewed from a side surface.

As illustrated in FIGS. 2A to 2C, the power terminal 51 includes an extending portion 511 and the bond portion 512. The bond portion 512 is a plate-like portion bonded with the circuit pattern 22b. The extending portion 511 extends upward by bending from one end portion of the bond portion 512, and is configured to be able to electrically connect the circuit pattern 22b and an external device of the semiconductor device 1.

The bond portion 512 is provided with a penetrating portion 513 penetrating through the bond portion 512 in a thickness direction. In the example illustrated in FIGS. 2A to 2C, the penetrating portion 513 has a circular shape. At this time, the shape of the penetrating portion 513 may be a true circle at least from as a designed shape. Nevertheless, this does not mean the finished shape of the penetrating portion 513 is also a true circle, from the perspective of processing accuracy or the like.

Further, it is preferable that a width of a predetermined distance or more is left from an outer rim portion of the penetrating portion 513 to each end portion of the bond portion 512 in such a manner that sufficient strength of the entire bond portion 512 is maintained. As an example, in a case where the thickness of the bond portion 512 is 1 mm or more and 1.5 mm or less, if a width of 1 mm or more is maintained from the outer rim portion of the penetrating portion 513 to end portion of the bond portion 512, sufficient strength is considered to be ensured.

As illustrated in FIG. 2B, the penetrating portion 513 is provided on the bottom surface of the bond portion 512 (i.e., at the central portion of a bonded surface with the circuit pattern 22b of the bond portion 512). In other words, a central point of the penetrating portion 513 viewed from the top surface substantially coincides with the central point of the bonded surface of the bond portion 512. Here, the case where the central point substantially coincides with the central point can include an error of a positional shift generated when the penetrating portion 513 is formed, or the like, aside from a case where the central point of the penetrating portion 513 and the central point of the bond portion 512 are perfectly-matched.

Such a penetrating portion 513 can be formed by wire electrical discharge machining or the like, for example. In the wire electrical discharge machining, for example, current is flown to a wire made of brass, and electrical discharge is generated between the wire and the bond portion 512 being a processing target. The bond portion 512 being a processing target is partially melt and cut by the electrical discharge heat.

Nevertheless, the penetrating portion 513 may be formed by another method that uses electron beam irradiation, laser irradiation, or the like.

The Cu sintered material 60 is interposed between the bottom surface of the bond portion 512 and the top surface of the circuit pattern 22b to bonds these.

Further, the Cu sintered material 60 is filled also into the penetrating portion 513 of the bond portion 512. At this time, it is preferable that the Cu sintered material 60 reaches a height position of an upper end portion of the penetrating portion 513, and an upper end portion of the Cu sintered material 60 may slightly protrude from a top surface of the bond portion 512. In this manner, by the Cu sintered material 60 being filled into the penetrating portion 513, an anchor effect by the Cu sintered material 60 is obtained, shear strength increases in a bonded portion between the power terminal 51 and the Cu sintered material 60, and a highly-reliable bond portion is obtained.

Further, at this time, an allowable thickness of the Cu sintered material 60 in the penetrating portion 513 is preferably set to a thickness that does not prevent an organic solvent in the pressureless Cu paste from going out when the pressureless Cu paste is sintered. As an example, it is sufficient that a height from a bonded interface of the circuit pattern 22b and the Cu sintered material 60 to the upper end portion of the Cu sintered material 60 that protrudes from the penetrating portion 513 is set to a height smaller than 1.5 times of the thickness of the bond portion 512 itself. In other words, it is sufficient that a protruding height of the Cu sintered material 60 from the penetrating portion 513 is smaller than a half of the thickness of the bond portion 512.

Nevertheless, as a state in which both of shear strength improvement by the Cu sintered material 60 and effluence of an organic solvent during sintering are satisfied, it is more preferable that the top surface of the Cu sintered material 60 in the penetrating portion 513 is at a height position substantially equal to the top surface of the bond portion 512. The state in which the top surface is at the substantially equal height position can include an error of a fill amount in filling the Cu sintered material 60, aside from a case where the top surface of the Cu sintered material 60 and the top surface of the bond portion 512 are completely equal in height.

Further, the Cu sintered material 60 has a skirt shape, and covers the side surface of the bond portion 512. That is, the Cu sintered material 60 has a taper shape spreading from the top surface of the bond portion 512 toward the circuit pattern 22b of the circuit board 20 on the side surface of the bond portion 512. Nevertheless, a taper portion of the Cu sintered material 60 may warp in a portion from the top surface of the bond portion 512 to the circuit pattern 22b. That is, an inclined surface of the taper portion of the Cu sintered material 60 may have a curved surface shape.

FIG. 3 is an enlarged perspective view of a bond portion 522 included in the signal terminal 52 according to an embodiment.

As illustrated in FIG. 3, the signal terminal 52 includes an extending portion 521 and the bond portion 522. The bond portion 522 is a plate-like portion bonded with the circuit pattern 22b. The extending portion 521 extends upward by bending from one end portion of the bond portion 522, and is configured to be able to electrically connect the circuit pattern 22b and an external device of the semiconductor device 1.

Further, the bond portion 522 of the signal terminal 52 may be formed in a size smaller than that of the bond portion 512 of the power terminal 51, for example. In other words, a bonded surface with the circuit pattern 22b of the bond portion 522 of the signal terminal 52 may have an area smaller than that of a bonded surface of the bond portion 512 of the power terminal 51. This is because an amount of current flowing in the signal terminal 52 tends to be smaller than an amount of current flowing in the power terminal 51.

In addition, a penetrating portion like the bond portion 512 of the power terminal 51 is not formed in the bond portion 522 of the signal terminal 52.

The Cu sintered material 60 is interposed between the bottom surface of the bond portion 522 and the top surface of the circuit pattern 22b to bonds these.

Further, the Cu sintered material 60 has a skirt shape, and covers the side surface of the bond portion 522. That is, the Cu sintered material 60 has a taper shape spreading from the top surface of the bond portion 522 toward the circuit pattern 22b of the circuit board 20 on the side surface of the bond portion 522. Nevertheless, a taper portion of the Cu sintered material 60 may warp in a portion from the top surface of the bond portion 522 to the circuit pattern 22b. That is, also in the bond portion 522 of the signal terminal 52, an inclined surface of the taper portion of the Cu sintered material 60 may have a curved surface shape.

In addition, in FIGS. 2A to 3, the extending portion 511 of the power terminal 51 and the bond portion 512, and the extending portion 521 of the signal terminal 52 and the bond portion 522 each have a portion bending approximately orthogonally. Nevertheless, these bending portions may have an obtuse angle. Further, the extending portion 511 and the bond portion 512, and the extending portion 521 and the bond portion 522 may be connected by a gentle curved surface.

In this manner, the shape of the bending portion can vary in various ways depending on a method of a bending work or the like in forming the power terminal 51 and the signal terminal 52 respectively having the bond portions 512 and 522, by bending an elongated metal material.

### (Manufacturing Method of Semiconductor Device)

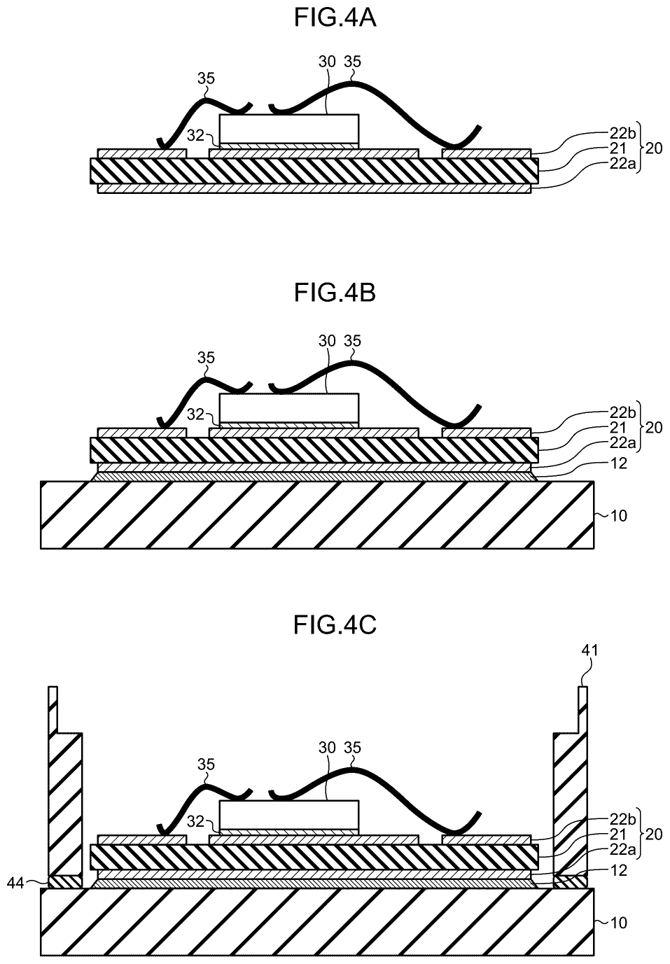

Next, an example of a manufacturing method of the semiconductor device 1 according to an embodiment will be described using FIGS. 4A to 7B. FIGS. 4A to 7B are longitudinal sectional views illustrating an example of a procedure of a manufacturing method of the semiconductor device 1 according to an embodiment.

As illustrated in FIG. 4A, by arranging the semiconductor chip 30 on the circuit pattern 22b of the circuit board 20 via Cu paste, Ag paste, or the like, and sintering the Cu paste or the Ag paste by heating the Cu paste or the Ag paste, the sintered material 32 that fixes the circuit pattern 22b and the semiconductor chip 30 is formed.

In addition, when the Cu paste or the Ag paste is sintered, by applying load to the semiconductor chip 30 together with heating the Cu paste or the Ag paste, the semiconductor chip 30 may be fixed onto the circuit board 20 more firmly.

Further, the wire 35 that connects a gate electrode and a source electrode (not illustrated) of the semiconductor chip 30 on the top surface of the semiconductor chip 30, and the circuit pattern 22b of the circuit board is formed. The gate electrode and the source electrode of the semiconductor chip 30, and the circuit pattern 22b of the circuit board and the wire 35 can be connected by ultrasonic bonding that uses ultrasonic waves, for example.

As illustrated in FIG. 4B, the circuit board 20 on which the semiconductor chip 30 is mounted is fixed onto the base plate 10. More specifically, the circuit pattern 22a on the rear surface of the circuit board 20, and the base plate 10 are bonded using the solder 12, for example.

As illustrated in FIG. 4C, the case 41 having a rectangular shape or the like that constitutes a part of the package 40 is fixed by the joining material 44 onto the base plate 10 in such a manner as to surround the circuit board 20 and the semiconductor chip 30.

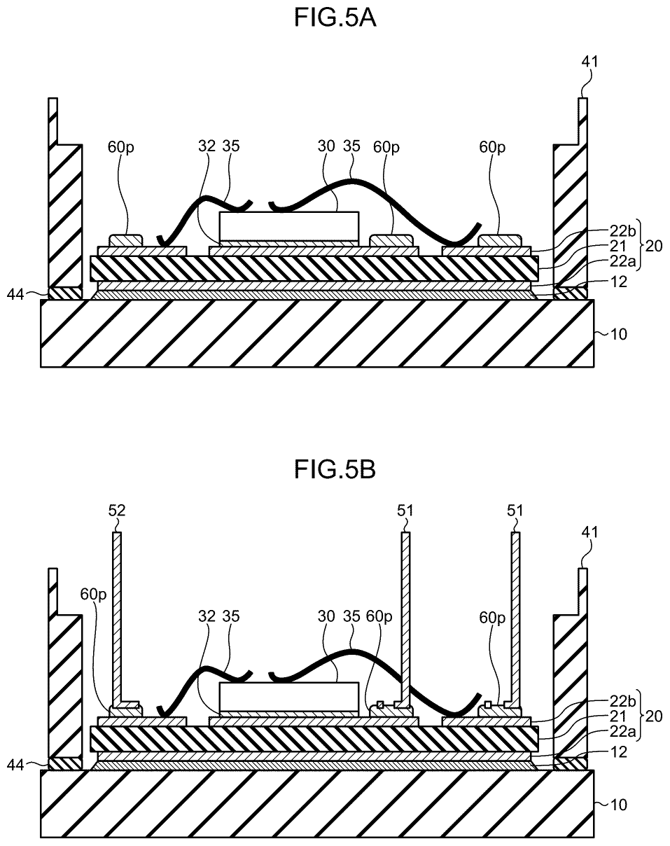

As illustrated in FIG. 5A, pressureless Cu paste 60p is applied using a dispenser or the like to a portion on the circuit pattern 22b of the circuit board 20 to which the power terminal 51 and the signal terminal 52 are to be connected.

As illustrated in FIG. 5B, the power terminal 51 and the signal terminal 52 are arranged on the circuit pattern 22b of the circuit board 20 via the pressureless Cu paste 60p.

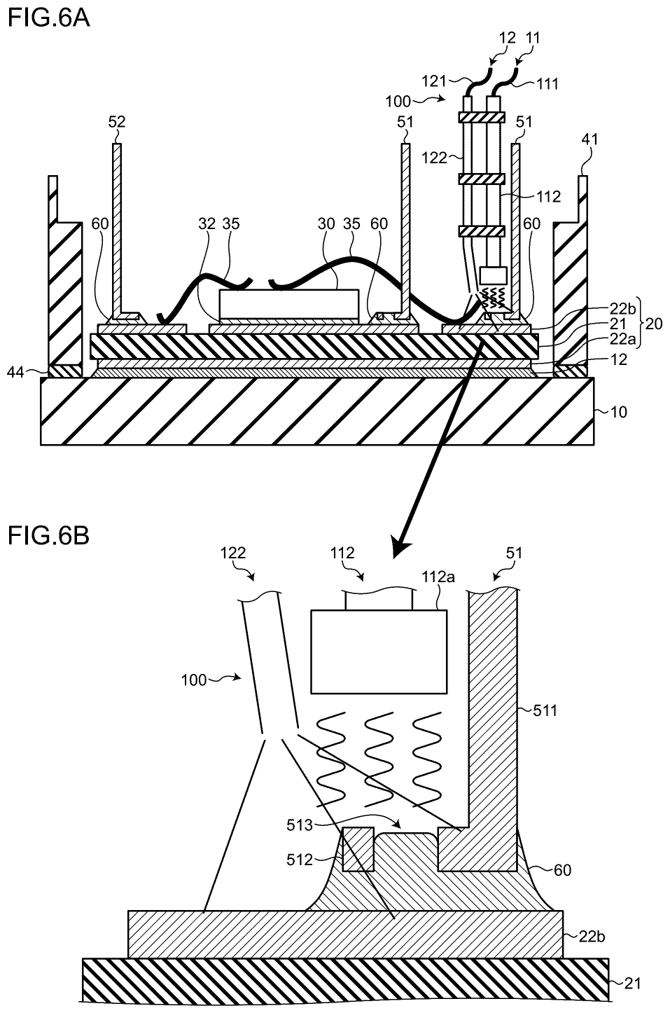

As illustrated in FIG. 6A, the pressureless Cu paste 60p interposed between the power terminal 51 and the signal terminal 52, and the circuit pattern 22b of the circuit board 20 is sequentially heated and sintered. At this time, it is preferable to use a local heating device 100 that can locally heat the pressureless Cu paste 60p.

The local heating device 100 includes a local heating unit 11 and an inactive gas supply unit 12.

The local heating unit 11 includes a power supply line 111, and a heater 112 to which the power supply line 111 is connected. By supplying power from the power supply line 111 to the heater 112, it is possible to cause the heater 112 to produce heat. The heater 112 may be a halogen heater or the like, for example.

The inactive gas supply unit 12 includes an inactive gas supply line 121, and an inactive gas supply pipe 122 to which the inactive gas supply line 121 is connected. An inactive gas supply source (not illustrated) is connected to a different end portion of the inactive gas supply line 121. The inactive gas supply unit 12 can spray inactive gas such as nitrogen or noble gas, for example, to a portion heated by the local heating unit 11, via the inactive gas supply line 121 and the inactive gas supply pipe 122.

When the pressureless Cu paste 60p is sintered, in a case where the entire semiconductor device 1 being manufactured is heated, or the like, for example, a defect attributed to melting of the solder 12 that connects the base plate 10 and the circuit board 20, or the like can be generated. Nevertheless, by locally heating the pressureless Cu paste 60p interposed between the power terminal 51 and the signal terminal 52, and the circuit pattern 22b of the circuit board 20, using the local heating device 100, for example, it is possible to prevent another member from being heated as well.

Further, by heating a bonded portion including the pressureless Cu paste 60p, using the local heating device 100, while spraying inactive gas, it is possible to prevent the surfaces of the bond portions 512 and 522 of the power terminal 51 and the signal terminal 52, and a bonded portion of the circuit pattern 22b of the circuit board 20 or the like from being oxidized, for example.

In addition, as a method of locally heating the pressureless Cu paste 60p, laser irradiation or the like is also conceivable. Nevertheless, because sputtering occurs in laser irradiation, chippings of members irradiated with laser, such as the bond portions 512 and 522 or the circuit pattern 22b might scatter, which is not preferable.

FIG. 6B is an enlarged longitudinal sectional view in a bonded portion of the power terminal 51 that illustrates a state of heating by the local heating device 100. As illustrated in FIG. 6B, when performing heating by the local heating device 100, heating is executed by bringing an extremely small-sized heating head 112a provided at the leading end of the heater 112, closer to the bond portion 512 of the power terminal 51, the circuit pattern 22b of the circuit board 20, the pressureless Cu paste 60p, and the like in a noncontact manner, while spraying inactive gas from the inactive gas supply pipe 122.

The pressureless Cu paste 60p is thereby heated, and an organic solvent in the pressureless Cu paste 60p is vaporized, and goes out from the inside of the pressureless Cu paste 60p. Further, as the organic solvent is vaporized, the density of Cu particles in the pressureless Cu paste 60p increases, and the Cu particles bond with each other. Further, the shape of the pressureless Cu paste 60p in a paste state accordingly changes.

Specifically, the pressureless Cu paste 60p interposed between the bond portion 512 of the power terminal 51 and the circuit pattern 22b of the circuit board 20 wetly spreads to the surrounding, and covers the side surface of the bond portion 512, and the Cu sintered material 60 having a skirt shape extending toward the circuit pattern 22b is formed. In addition, in the case of pressed Cu past to be sintered while load being applied, such a skirt shape cannot be obtained.

Further, the pressureless Cu paste 60p upthrusts from the bottom surface side of the bond portion 512 of the power terminal 51 into the penetrating portion 513, and the Cu sintered material 60 filled into the penetrating portion 513 is obtained. At this time, in order to prevent the top surface of the Cu sintered material 60 filled into the penetrating portion 513, from protruding by a half of the thickness of the bond portion 512 or more, an original application amount of the pressureless Cu paste 60p is preferably adjusted in such a manner that the top surface of the Cu sintered material 60 is more preferably at a height position approximately equal to the top surface of the bond portion 512.

In addition, also in the bond portion 522 of the signal terminal 52, when performing heating by the local heating device 100, heating is executed by bringing the heating head 112a at the leading end of the heater 112 closer to the bond portion 522 of the signal terminal 52, the circuit pattern 22b of the circuit board 20, the pressureless Cu paste 60p, and the like in a noncontact manner, while spraying inactive gas from the inactive gas supply pipe 122, which is not illustrated in the drawing.

An organic solvent is thereby vaporized, and goes out from the inside of the pressureless Cu paste 60p, and Cu particles in the pressureless Cu paste 60p bond with each other. Further, the shape of the pressureless Cu paste 60p in a paste state accordingly changes.

In the bond portion 522 of the signal terminal 52 not having a penetrating portion, the pressureless Cu paste 60p interposed between the bond portion 512 of the bond portion 522 and the circuit pattern 22b wetly spreads to the surrounding, and covers the side surface of the bond portion 522, and the Cu sintered material 60 having a skirt shape extending toward the circuit pattern 22b is formed.

In this manner, by using the Cu sintered material 60 obtained by sintering the pressureless Cu paste 60p, for example, it is possible to connect the power terminal 51 and the signal terminal 52, and the circuit pattern 22b of the circuit board 20 without applying load.

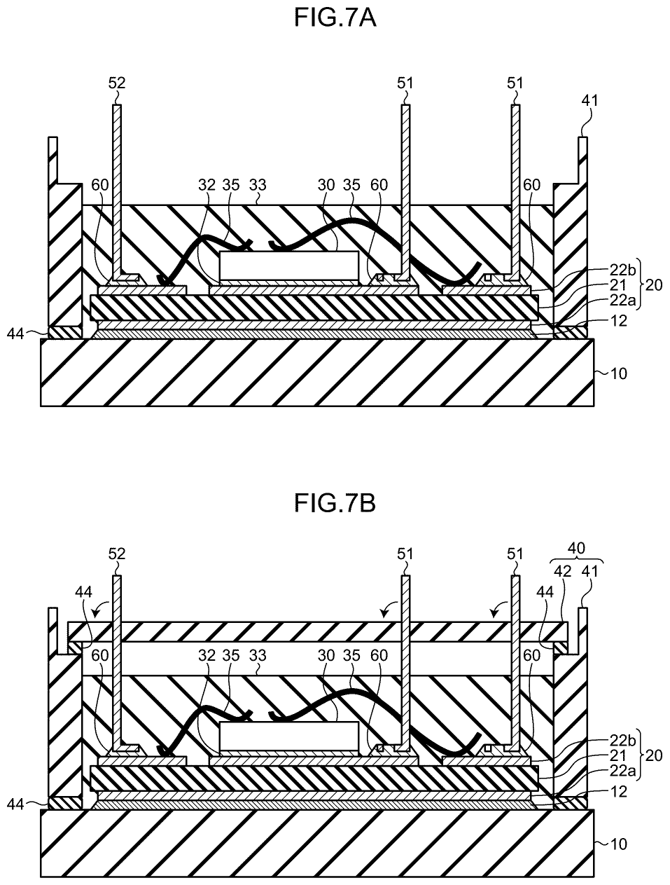

As illustrated in FIG. 7A, the potting material 33 is injected into a space surrounded by the base plate 10 and the case 41, and the semiconductor device 1 being manufactured is thermally cured within an oven. The potting material 33 is thereby cured, and the insulation property inside the case 41 is maintained.

As illustrated in FIG. 7B, the joining material 44 is interposed, and the lid 42 is overlaid at the upper end portion of the case 41 and fixed thereonto. After that, upper ends of the extending portions 511 and 521 of the power terminal 51 and the signal terminal 52 that protrude from the top surface of the lid 42 are bent.

As described above, the semiconductor device 1 of the embodiment is manufactured.

### Comparative Example

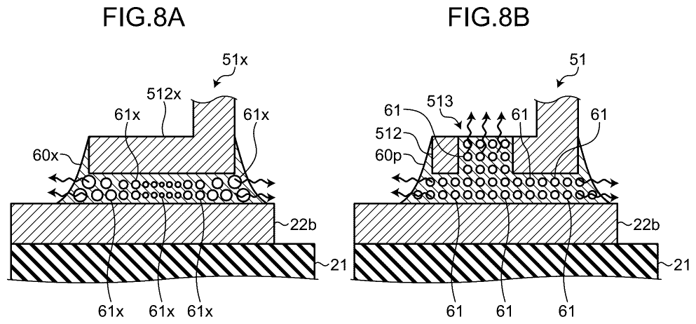

Next, an example of a case of connecting a power terminal 51x of a comparative example or the power terminal 51 of the embodiment to the circuit pattern 22b will be described using FIGS. 8A and 8B.

FIGS. 8A and 8B are longitudinal sectional views illustrating states of connection of the power terminals 51 and 51x according to an embodiment and a comparative example to the circuit pattern 22b. More specifically, FIG. 8A illustrates a state of connecting the power terminal 51x of the comparative example to the circuit pattern 22b, and FIG. 8B illustrates a state of connecting the power terminal 51 of the embodiment to the circuit pattern 22b.

As illustrated in FIG. 8A, the power terminal 51x of the comparative example includes a bond portion 512x bonded to the circuit pattern 22b. Nevertheless, a penetrating portion is not provided in the bond portion 512x. Local heating is executed by interposing pressureless Cu paste 60x between such a bond portion 512x and the circuit pattern 22b. An organic solvent in the pressureless Cu paste 60x is thereby vaporized, and goes out from the inside of the pressureless Cu paste 60x.

At this time, the organic solvent mainly goes out from the side surface of the pressureless Cu paste 60x that is exposed from a clearance gap between the bond portion 512x and the circuit pattern 22b. Thus, in a central portion of the pressureless Cu paste 60x, the density of Cu particles increases, and sintering progresses relatively promptly.

In contrast to this, in the vicinity of an end portion of the side surface of the pressureless Cu paste 60x, sintering is difficult to progress due to the organic solvent going out from the central portion of the pressureless Cu paste 60x, and air bubbles 61x are easily generated by vaporized organic solvent.

Such air bubbles 61x are generated also at the central portion of the pressureless Cu paste 60x, but the air bubbles 61x are more easily generated in the vicinity of the end portion than the central portion of the pressureless Cu paste 60x. Such air bubbles 61x remain as voids in a Cu sintered material formed by heating.

Accordingly, in the Cu sintered material of the comparative example, a sparse and dense difference that makes a central portion dense and an end portion sparse is generated in such a manner that the density of Cu particles at the central portion is higher than that in the vicinity of the end portion, and a void ratio in the vicinity of the end portion is higher than that at the central portion. Such a sparse and dense difference deteriorates an electric property and bonding strength at the bonded portion between the power terminal 51x and the circuit pattern 22b.

As illustrated in FIG. 8B, in the power terminal 51 of the embodiment, as described above, the penetrating portion 513 is provided in the bond portion 512. In this case, by local heating of the bonded portion, a vaporized organic solvent goes out not only from the side surface of the pressureless Cu paste 60p that is exposed from the clearance gap between the bond portion 512 and the circuit pattern 22b, but also from the upper end portion of the pressureless Cu paste 60p filled into the penetrating portion 513.

As described above, the penetrating portion 513 is provided at the central portion of the bonded surface with the circuit pattern 22b of the bond portion 512, and arranged immediately above the central portion of the pressureless Cu paste 60p. Accordingly, it is possible to reduce an amount of an organic solvent going out from the end portion vicinity of the side surface of the pressureless Cu paste 60p. Further, it is possible to suppress a variation in amount of a vaporized organic solvent going out, between the central portion of the pressureless Cu paste 60p and the end portion vicinity of the side surface of the pressureless Cu paste 60p, and uniformize the progress of sintering and generation easiness of the air bubbles 61 by the vaporized organic solvent.

With this configuration, also in the Cu sintered material 60 formed by heating, variations in the density of Cu particles and a void ratio between the central portion and the end portion vicinity are suppressed, and the Cu sintered material 60 with a small sparse and dense difference is obtained. Further, it is accordingly possible to decrease an overall void ratio of the Cu sintered material 60. For this reason, it is possible to improve an electric property at the bonded portion between the power terminal 51 and the circuit pattern 22b. Here, the void ratio is, for example, a percentage of an area occupied by voids with respect to an area occupied by the Cu sintered material 60, in a cross section cut in a direction vertical to a thickness direction of the bond portion 512.

In addition, as described above, the bond portion 522 included in the signal terminal 52 of the embodiment has a configuration in which an area of a bonded surface with the circuit pattern 22b is smaller than the bond portion 512 of the power terminal 51, for example. Thus, without providing a penetrating portion in the bond portion 522 of the signal terminal 52, variations in the density of Cu particles and a void ratio between the central portion and the end portion vicinity are suppressed during sintering by heating, and the Cu sintered material 60 with a small sparse and dense difference is obtained.

### Overview

A semiconductor device includes, for example, a semiconductor chip mounted on a circuit board having a circuit pattern. Further, an external terminal such as a power terminal and a signal terminal is sometimes connected to the circuit pattern of the circuit board. The circuit pattern and the external terminal are connected by executing ultrasonic bonding while applying load, for example. For example, a plurality of protrusions is provided at the leading end portion of a bonding tool used in ultrasonic bonding, and by these protrusions biting into the external terminal and adding vibration by ultrasonic waves, the external terminal and the circuit pattern are firmly bonded.

Nevertheless, by the above-described method, by the application of load and vibration by ultrasonic waves, the circuit board might be damaged. Further, when protrusions at the leading end portion of the bonding tool bite into the external terminal, chippings of the external terminal are generated and scatter, and these sometimes short circuit nearby wirings such as the circuit pattern.

In order to solve the above-described problem, inventors of the present invention have considered a method of connecting an external terminal and a circuit pattern in a pressureless manner, and conceived using pressureless Cu paste. By heating and sintering the pressureless Cu paste, even in a pressureless state, firm bonding is obtained, and it is possible to connect the external terminal and the circuit pattern with high reliability.

Nevertheless, in a case where the pressureless Cu paste is used, heat generated during sintering also heats another member, and for example, solder or the like that fixes a circuit board and a base plate might melt. Further, it has been revealed that, when the pressureless Cu paste is sintered, while sintering progresses relatively promptly at the central portion of the pressureless Cu paste, sintering does not progress at the end portion vicinity, and a void ratio also increases to cause a sparse state. The inventors of the present invention have further earnestly conducted researches, and have eventually solved the above problems.

According to the semiconductor device 1 of the embodiment, the power terminal 51 that contains metal of the same type as the circuit pattern 22b of the circuit board 20, and is electrically-connected with the circuit pattern 22b is included, and the bond portion 512 of the power terminal 51 and the circuit pattern 22b are bonded by the Cu sintered material 60 containing particles of metal of the same type as the power terminal 51 and the circuit pattern 22b.

In this manner, by using the Cu sintered material 60 in the connection between the circuit pattern 22b and the power terminal 51, it is possible to bond the power terminal 51 to the circuit pattern 22b while suppressing damages to the circuit pattern 22b, the power terminal 51, and the like. Further, chippings are prevented from scattering from the power terminal 51 and short circuiting nearby wirings or the like. For this reason, the semiconductor device 1 with high reliability can be obtained. Further, by using the Cu sintered material 60 containing metal of the same type as the circuit pattern 22b and the power terminal 51, it is possible to firmly bond the circuit pattern 22b and the power terminal 51.

According to the semiconductor device 1 of the embodiment, the power terminal 51 includes the bond portion 512 bonded with the circuit pattern 22b, and the penetrating portion 513 penetrating through the bond portion 512 in the thickness direction of the bond portion 512.

In this manner, by the bond portion 512 including the penetrating portion 513, it is possible to reduce a sparse and dense difference between the central portion and the end portion vicinity of the Cu sintered material 60, and decrease a void ratio of the entire Cu sintered material 60. With this configuration, by improving an electric property and bonding strength at the bonded portion between the bond portion 512 and the circuit pattern 22b, it is possible to connect the power terminal 51 and the circuit pattern 22b highly reliably.

According to the semiconductor device 1 of the embodiment, the Cu sintered material 60 is interposed between the bond portion 512 and the circuit pattern 22b, and also filled into the penetrating portion 513. With this configuration, it is possible to enhance bonding strength between the bond portion 512 and the circuit pattern 22b to stress of shearing the bond portion 512 and the circuit pattern 22b (i.e., shear stress).

According to the semiconductor device 1 of the embodiment, the Cu sintered material 60 has a skirt shape to cover the side surface of the bond portion 512. As described above, by using pressureless Cu paste instead of pressed Cu paste, it is possible to form the Cu sintered material 60 with such a shape during sintering. By the Cu sintered material 60 having a skirt shape, it is possible to further enhance bonding strength between the bond portion 512 and the circuit pattern 22b.

According to the semiconductor device 1 of the embodiment, the penetrating portion 513 has a circular shape when viewed from the top surface of the bond portion 512, and the central point of the penetrating portion 513 viewed from the top surface of the bond portion 512 substantially coincides with the central point of the bonded surface with the circuit pattern 22b of the bond portion 512. By providing the penetrating portion 513 at such a position, it is possible to further reduce a sparse and dense difference between the central portion and the end portion vicinity of the Cu sintered material 60.

According to the semiconductor device 1 of the embodiment, the signal terminal 52 that contains metal of the same type as the circuit pattern 22b, and is electrically-connected with the circuit pattern 22b is further included, and the Cu sintered material 60 is interposed also between the bond portion 522 of the signal terminal 52 and the circuit pattern 22b. In this manner, by applying the Cu sintered material 60 also to the bonded portion between the signal terminal 52 and the circuit pattern 22b, it is possible to bond the signal terminal 52 to the circuit pattern 22b while suppressing damages.

According to the semiconductor device 1 of the embodiment, the bond portion 522 included in the signal terminal 52 is smaller than the bond portion 512 included in the power terminal 51, and the penetrating portion 513 is selectively formed in the bond portion 512 of the power terminal 51 out of the bond portion 512 of the power terminal 51 and the bond portion 522 of the signal terminal 52. In this manner, the bond portion 522 of the signal terminal 52 is often formed in a size smaller than that of the bond portion 512 of the power terminal 51, and in this case, without providing a penetrating portion in the bond portion 522 of the signal terminal 52, it is possible to suppress a variation in a sparse and dense difference between the central portion and the end portion vicinity of the Cu sintered material 60.

According to the manufacturing method of the semiconductor device 1 of the embodiment, when the power terminal 51 and the circuit pattern 22b are connected, without applying load to the power terminal 51 and the circuit pattern 22b, sintering is executed by locally heating the pressureless Cu paste 60p. With this configuration, for example, it is possible to bond the power terminal 51 to the circuit pattern 22b while suppressing damages caused by application of load and ultrasonic bonding. Further, because the pressureless Cu paste 60p is locally heated, it is possible to prevent another member from being heated and damaged as well.

According to the manufacturing method of the semiconductor device 1 of the embodiment, when the pressureless Cu paste 60p is sintered, the pressureless Cu paste 60p is locally heated by bringing the heating head 112a of the heater 112 closer to the bond portion 512 without contact with the bond portion 512 of the power terminal 51, while spraying inactive gas to the pressureless Cu paste 60p.

In this manner, by sintering the pressureless Cu paste 60p by local heating, it is possible to prevent another member from being heated as well. Further, by spraying inactive gas during heating of the pressureless Cu paste 60p, it is possible to prevent oxidation of the bond portion 512 and the circuit pattern 22b.

According to the manufacturing method of the semiconductor device 1 of the embodiment, when the pressureless Cu paste 60p is interposed between the bond portion 512 and the circuit pattern 22b, a used amount of the pressureless Cu paste 60p is adjusted in such a manner that the thickness in the penetrating portion 513 from a bonding interface with the circuit pattern 22b of the Cu sintered material 60 generated by the pressureless Cu paste 60p being sintered, to an upper end portion becomes equal to or larger than the thickness of the bond portion 512, and smaller than 1.5 times of the thickness of the bond portion 512.

In this manner, by causing a state in which the Cu sintered material 60 is sufficiently filled into the penetrating portion 513, bonding strength between the bond portion 512 and the circuit pattern 22b to shear stress increases. On the other hand, because there is no need to sinter excessive pressureless Cu paste 60p significantly exceeding the top surface of the bond portion 512, it becomes easier to sinter the pressureless Cu paste 60p, and also shorten a sintering time.

### Modified Example 1

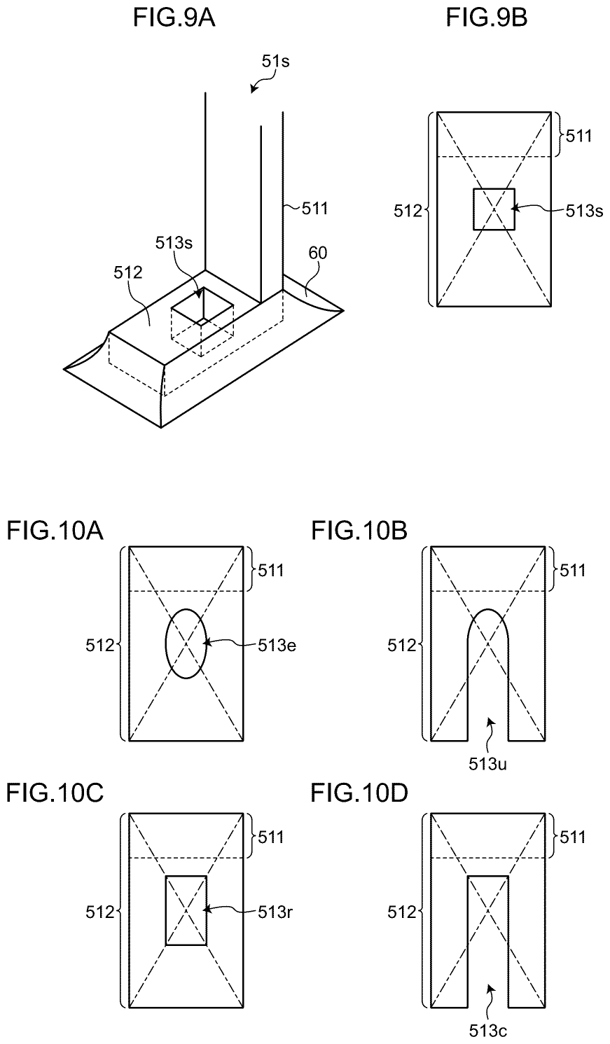

Next, a semiconductor device of a Modified Example 1 of the embodiment will be described using FIGS. 9A and 9B. The semiconductor device of Modified Example 1 differs from the above-described embodiment in the shape of a penetrating portion 513s included by a power terminal 51s in a bond portion 512.

FIGS. 9A and 9B are enlarged views of a bond portion 512 included in a power terminal 51s according to Modified Example 1 of an embodiment. More specifically, FIG. 9A is a perspective view of the bond portion 512, and FIG. 9B is a bottom-side plan view of the bond portion 512.

In addition, in FIGS. 9A and 9B, the components similar to the components in the above-described embodiment are assigned similar reference numerals, and the description thereof will be omitted in some cases.

As illustrated in FIGS. 9A and 9B, in the bond portion 512 included in the power terminal 51s of Modified Example 1, the penetrating portion 513s having a quadrangular shape when viewed from the top surface is provided. At this time, the shape of the penetrating portion 513s may be a square at least from as a designed shape. Nevertheless, this does not mean the finished shape of the penetrating portion 513s is also a square, from the perspective of processing accuracy or the like.

As illustrated in FIG. 9B, the penetrating portion 513 of Modified Example 1 is also provided on the bottom surface of the bond portion 512 (i.e., at the central portion of a bonded surface with the circuit pattern 22b of the bond portion 512). In other words, a central point of the penetrating portion 513s viewed from the top surface substantially coincides with the central point of the bonded surface of the bond portion 512.

Such a penetrating portion 513 of Modified Example 1 can also be formed by wire electrical discharge machining or the like, for example.

According to the semiconductor device 1 of Modified Example 1, the penetrating portion 513s has a quadrangular shape when viewed from the top surface of the bond portion 512, and the central point of the penetrating portion 513s viewed from the top surface of the bond portion 512 substantially coincides with the central point of the bonded surface with the circuit pattern 22b of the bond portion 512. With this configuration, an effect similar to that of the semiconductor device of the above-described embodiment is caused.

Further, in a case where a width of the penetrating portion 513s is made equal to a diameter of the circular penetrating portion 513 of the above-described embodiment, an opening area in the bond portion 512 of the quadrangular penetrating portion 513s becomes larger. With this configuration, it is possible to further increase an amount by which an organic solvent goes out from the central portion upper end of the pressureless Cu paste 60p. For this reason, it is possible to further reduce a sparse and dense difference between the central portion and the end portion vicinity of the Cu sintered material 60, and decrease a void ratio of the entire Cu sintered material 60.

### Modified Example 2

Next, a semiconductor device of a Modified Example 2 of the embodiment will be described using FIGS. 10A to 10D. In the semiconductor device of Modified Example 2, penetrating portions 513e, 513u, 513r, and 513c included by a power terminal in the bond portion 512 have a shape further different from that of the above-described embodiment.

FIGS. 10A to 10D are bottom-side plan views of a bond portion 512 included in a power terminal according to Modified Example 2 of an embodiment. In addition, in FIGS. 10A to 10D, the components similar to the components in the above-described embodiment are assigned similar reference numerals, and the description thereof will be omitted in some cases.

In the example in FIG. 10A, a penetrating portion 513e of Modified Example 2 has an ellipsoidal shape with a long axis extending in a long direction of the bond portion 512. The penetrating portion 513e of Modified Example 2 that has an ellipsoidal shape is also provided on the bottom surface of the bond portion 512 (i.e., at the central portion of a bonded surface with the circuit pattern 22b of the bond portion 512). In other words, a central point of the penetrating portion 513e viewed from the top surface substantially coincides with the central point of the bonded surface of the bond portion 512.

In the example in FIG. 10B, the penetrating portion 513u of Modified Example 2 is opened toward a different end portion side that is opposite side of one end portion of the bond portion 512 that has a bend portion with the extending portion 511. Further, on one end portion side of the bond portion 512, an end portion of the penetrating portion 513u has a curved surface. In other words, the penetrating portion 513u viewed from the top surface has a U shape.

In the example in FIG. 10C, a penetrating portion 513r of Modified Example 2 has an oblong shape with a long axis extending in a long direction of the bond portion 512. The penetrating portion 513r of Modified Example 2 that has an oblong shape is also provided on the bottom surface of the bond portion 512 (i.e., at the central portion of a bonded surface with the circuit pattern 22b of the bond portion 512). In other words, a central point of the penetrating portion 513r viewed from the top surface substantially coincides with the central point of the bonded surface of the bond portion 512.

In the example in FIG. 10D, the penetrating portion 513c of Modified Example 2 is opened toward a different end portion side that is opposite side of one end portion of the bond portion 512 that has a bend portion with the extending portion 511. Further, on one end portion side of the bond portion 512, an end portion of the penetrating portion 513c has a rectangular shape. In other words, the penetrating portion 513c viewed from the top surface has an oblong shape with a short side on one side being opened.

According to the semiconductor device of Modified Example 2, the shapes of the penetrating portions 513e, 513u, 513r, and 513c viewed from the top surface of the bond portion 512 have a longer direction and a shorter direction. With this configuration, an effect similar to that of the semiconductor device of the above-described embodiment is caused.

Further, in a case where widths in the shorter direction of the penetrating portion 513e and 513r are made equal to widths of the circular penetrating portion 513 of the above-described embodiment and the quadrangular penetrating portion 513s of Modified Example 1 described above, the penetrating portions 513e and 513r of Modified Example 2 have a larger opening area in the bond portion 512. With this configuration, it is possible to further increase an amount by which an organic solvent goes out from the central portion upper end of the pressureless Cu paste 60p, further reduce a sparse and dense difference between the central portion and the end portion vicinity of the Cu sintered material 60, and decrease a void ratio of the entire Cu sintered material 60.

According to the semiconductor device of Modified Example 2, the penetrating portions 513u and 513c are opened toward the different end portion side of the bond portion 512. With this configuration, it is possible to further enlarge an opening area in the bond portion 512. For this reason, it is possible to further increase an amount by which an organic solvent goes out from the central portion upper end of the pressureless Cu paste 60p, further reduce a sparse and dense difference between the central portion and the end portion vicinity of the Cu sintered material 60, and decrease a void ratio of the entire Cu sintered material 60.

In addition, in the above-described embodiment and Modified Examples 1 and 2, the semiconductor chip 30 includes the semiconductor chip 30 made of SiC. Nevertheless, even if the semiconductor chip 30 is made of another material such as Si, GaAs, or GaN, for example, the configurations of the above-described embodiment and Modified Examples 1 and 2 are applicable. Further, the semiconductor chip 30 is not limited to the above-described MOSFET, and may be a semiconductor chip of a type different from the MOSFET, such as an insulated gate bipolar transistor (IGBT), for example.

Further, in the above-described embodiment and Modified Examples 1 and 2, each of the penetrating portions 513, 513s, 513e, 513u, 513r, and 513c is provided only by one. Nevertheless, a plurality of penetrating portions may be provided in the bond portion 512.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
an insulating board having a circuit pattern;
a semiconductor chip fixed on the insulating board and electrically-connected with the circuit pattern; and
a power terminal that includes metal of a same type as the circuit pattern, and is electrically-connected with the circuit pattern,
wherein the power terminal includes
a bond portion bonded with the circuit pattern, the bond portion having a plate shape,
a penetrating portion penetrating through the bond portion in a thickness direction of the bond portion, and
an extending portion that extends upward by bending from one end portion of the bond portion, and is configured to be able to connect the circuit pattern and an external device, and
the bond portion and the circuit pattern are bonded by a bonding material containing particles of metal of a same type as the power terminal and the circuit pattern.

2. The semiconductor device according to claim 1,
wherein the bonding material is interposed between the bond portion and the circuit pattern, and filled into the penetrating portion.

3. The semiconductor device according to claim 2,
wherein a thickness of the bonding material in the penetrating portion from a bonding interface with the circuit pattern to an upper end portion of the bonding material is equal to or larger than a thickness of the bond portion, and smaller than 1.5 times of the thickness of the bond portion.

4. The semiconductor device according to claim 1,
wherein the bonding material has a skirt shape and covers a side surface of the bond portion.

5. The semiconductor device according to claim 1,
wherein the bonding material contains a void.

6. The semiconductor device according to claim 1,
wherein the bonding material derives from pressureless metal paste in which the particles are contained in an organic solvent that can be sintered in a pressureless manner.

7. The semiconductor device according to claim 1,
wherein the penetrating portion has a circular or quadrangular shape when viewed from a top surface of the bond portion.

8. The semiconductor device according to claim 1,
wherein a shape of the penetrating portion viewed from a top surface of the bond portion has a longer direction and a shorter direction.

9. The semiconductor device according to claim 8,
wherein the penetrating portion is opened toward another end portion relative to the one end portion of the bond portion.

10. The semiconductor device according to claim 7,
wherein a central point of the penetrating portion viewed from the top surface of the bond portion substantially coincides with a central point of a bonded surface with the circuit pattern of the bond portion.

11. The semiconductor device according to claim 1, further comprising
a signal terminal that contains metal of a same type as the circuit pattern, and is electrically-connected with the circuit pattern,
wherein the bonding material is interposed between a bond portion of the signal terminal and the circuit pattern.

12. The semiconductor device according to claim 11,
wherein the bond portion included in the signal terminal is smaller than the bond portion included in the power terminal, and
the penetrating portion is selectively formed in the bond portion of the power terminal out of the bond portion of the power terminal and the bond portion of the signal terminal.

13. A manufacturing method of a semiconductor device, the manufacturing method comprising:
fixing a semiconductor chip onto an insulating board having a circuit pattern, and electrically connecting with the circuit pattern; and
electrically connecting a power terminal containing metal of a same type as the circuit pattern, with the circuit pattern,
wherein the power terminal includes
a bond portion bonded with the circuit pattern, the bond portion having a plate shape,
a penetrating portion penetrating through the bond portion in a thickness direction of the bond portion, and
an extending portion extending upward by bending from one end portion of the bond portion,
the connecting the power terminal and the circuit pattern includes,
interposing pressureless metal paste between the bond portion of the power terminal and the circuit pattern, the pressureless metal paste containing particles of metal of a same type as the power terminal and the circuit pattern, the pressureless metal paste being capable of sintered in a pressureless manner, and
sintering the pressureless metal paste by being locally heated without applying load to the power terminal and the circuit pattern.

14. The manufacturing method of a semiconductor device according to claim 13,
wherein the sintering the pressureless metal paste includes, locally heating the pressureless metal paste by bringing a heating head of a heater, without contacting, closer to the bond portion of the power terminal, while sparing inactive gas to the pressureless metal paste.

15. The manufacturing method of a semiconductor device according to claim 13,
wherein the sintering the pressureless metal paste includes, filling the pressureless metal paste into the penetrating portion.

16. The manufacturing method of a semiconductor device according to claim 15,
wherein, the interposing the pressureless metal paste between the bond portion and the circuit pattern includes, adjusting a used amount of the pressureless metal paste in such a manner that a thickness in the penetrating portion from a bonding interface with the circuit pattern of a bonding material generated by the pressureless metal paste being sintered, to an upper end portion is equal to or larger than a thickness of the bond portion, and smaller than 1.5 times of a thickness of the bond portion.

17. The manufacturing method of a semiconductor device according to claim 13,
wherein the penetrating portion has a circular or quadrangular shape when viewed from a top surface of the bond portion.

18. The manufacturing method of a semiconductor device according to claim 13,
wherein a shape of the penetrating portion viewed from a top surface of the bond portion has a longer direction and a shorter direction.

19. The manufacturing method of a semiconductor device according to claim 18,
wherein the penetrating portion is opened toward another end portion relative to the one end portion of the bond portion.

20. The manufacturing method of a semiconductor device according to claim 17,
wherein a central point of the penetrating portion viewed from the top surface of the bond portion substantially coincides with a central point of a bonded surface with the circuit pattern of the bond portion.
